(19) United States
(12) Patent Application Publication
(10) Pub. No.: US 2025/0351296 A1
(43) Pub. Date: Nov. 13, 2025

(54) RADIATOR UNIT, RADIATOR MODULE AND SERVER

(71) Applicant: WISTRON CORP., New Taipei City (TW)

(72) Inventors: CHENG YU LIN, New Taipei City (TW); Yu Chuan Wu, New Taipei City (TW); Yu-Jei Huang, New Taipei City (TW)

(21) Appl. No.: 18/793,096

(22) Filed: Aug. 2, 2024

(30) Foreign Application Priority Data
May 8, 2024 (TW) 113116987

(51) Int. Cl. H05K 7/20

(52) U.S. Cl. CPC H05K 7/20263; H05K 7/20272; H05K 7/20772; H05K 7/20254

(57) ABSTRACT

A radiator unit is configured to be assembled with another radiator unit. The radiator unit includes a main body and two expansion joints. The main body includes a channel portion. The two expansion joints communicate with the channel portion. One of the two expansion joints is configured to be assembled with the another radiator unit.

### CROSS-REFERENCE TO RELATED APPLICATIONS

This non-provisional application claims priority under 35 U.S.C. § 119 (a) on Patent Application No(s). 113116987 filed in Taiwan, R.O.C. on May 8, 2024, the entire contents of which are hereby incorporated by reference.

### TECHNICAL FIELD

The disclosure relates to a radiator unit, a radiator module and a server.

### BACKGROUND

Heat dissipation modules on the market are generally made of one piece and are required to be customized according to different heat dissipation requirements. However, such heat dissipation modules are unable to be applied to various kinds of configuration or designs, and thus manufacturers require to spend a lot of time in designing different kinds of heat dissipation modules, which requires a huge amount of manpower, reduces the manufacturing efficiency and increases costs. Moreover, the heat dissipation efficiencies of different heat dissipation modules are also very different, and it is difficult to evaluate them according to specific standards. Therefore, it is necessary to rely on experience to make the heat dissipation modules meet requirements.

### SUMMARY

The disclosure provides a radiator unit, a radiator module and a server which are capable of improving the manufacturing efficiency, reduce the cost and providing a desired heat dissipation efficiency.

One embodiment of the disclosure provides a radiator unit. The radiator unit is configured to be assembled with another radiator unit. The radiator unit includes a main body and two expansion joints. The main body includes a channel portion. The two expansion joints communicate with the channel portion. One of the two expansion joints is configured to be assembled with the another radiator unit.

Still another embodiment of the disclosure provides a radiator module. The radiator module includes a plurality of radiator units. Each of the radiator units includes a main body and two expansion joints. The main body includes a channel portion. The expansion joints communicate with the channel portion. The channel portions of the main bodies of the radiator units are assembled with one another via the expansion joints.

Still another embodiment of the disclosure provides a server. The server includes a casing and a radiator module. The radiator module is located in the casing and includes a plurality of radiator units and two expansion joints. Each of the radiator units includes a main body and two expansion joints. The main body includes a channel portion. The two expansion joints communicate the channel portion. The channel portions of the main bodies of the radiator units are assembled with one another via the expansion joints.

According to the radiator units, the radiator modules and the server as discussed in the above embodiments, the channel portion of the main body of each of the radiator unit is provided with the two expansion joints, and the channel portions of the main bodies of the radiator units are assembled with one another via the expansion joints so as to become a module. Therefore, a user can choose the quantity of the radiator unit which are desired to be assembled with one another according to heat dissipation requirement.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial top view of a server according to a first embodiment of the disclosure;

FIG. 2 is a perspective view of a radiator module in FIG. 1;

FIG. 3 is an exploded view of the radiator module in FIG. 2;

FIG. 4 is a cross-sectional view of a radiator unit in FIG. 2;

FIG. 5 is a top view of the radiator module in FIG. 2;

FIG. 6 is a side view of the radiator module in FIG. 2;

FIG. 7 is a top view of a radiator module according to a second embodiment of the disclosure;

FIG. 8 is a perspective view of a radiator module according to a third embodiment of the disclosure; and

FIG. 9 is a top view of the radiator module in FIG. 8.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

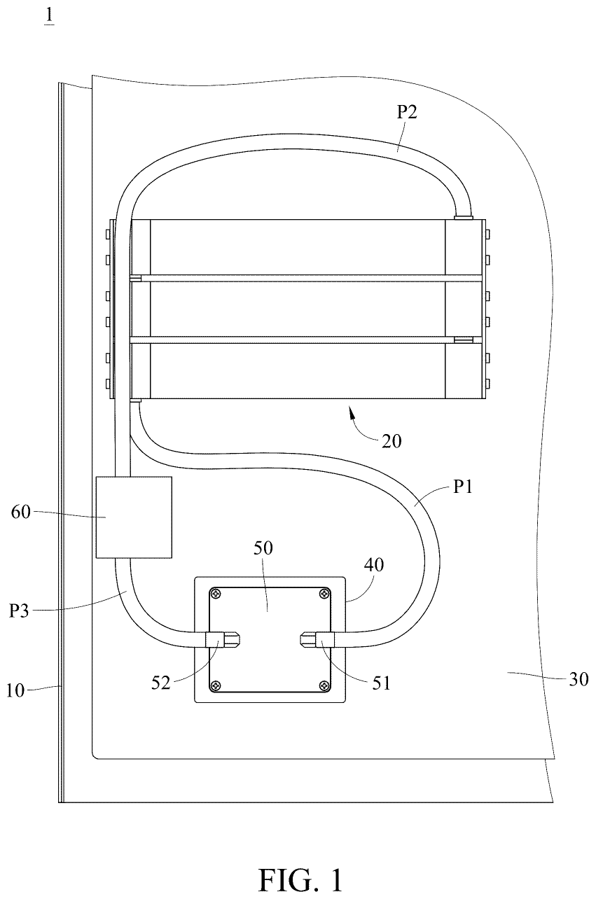

Referring to FIG. 1, FIG. 1 is a partial top view of a server according to a first embodiment of the disclosure.

In this embodiment, the server 1 includes a casing 10 and a radiator module 20. In addition, the server 1 may further include a motherboard 30, a heat source 40, a water block 50 and a pump 60.

The motherboard 30, the heat source 40, the water block 50 and the radiator module 20 are located in the casing 10. The heat source 40 is, for example, a CPU or a GPU. The heat source 40 is disposed on the motherboard 30. The water block 50 is stacked on the heat source 40 for absorbing heat generated by the heat source 40. An outlet joint 51 of the water block 50 is connected to the radiator module 20 via, for example, a pipe P1, the radiator module 20 is connected to the pump 60 via, for example, a pipe P2, and the pump 60 is connected to an inlet joint 52 of the water block 50 via, for example, a pipe P3. Therefore, the pump 60, the water block 50 and the radiator module 20 together form a loop for the circulation of a coolant. The pump 60 can drive the coolant to flow into the water block 50 for performing heat exchange with the water block 50, thereby taking heat absorbed from the heat source 40 by the water block 50 away. Then, the coolant flows to the radiator module 20, such that the radiator module 20 can dissipate heat absorbed by the coolant in a nature convection manner or a force convection manner so as to cool the coolant. Then, the pump 60 can drive the cooled coolant to flow back to the water block 50. As a result, the coolant keeps flowing the aforementioned loop, which enables the heat source 40 to operate in a desired temperature.

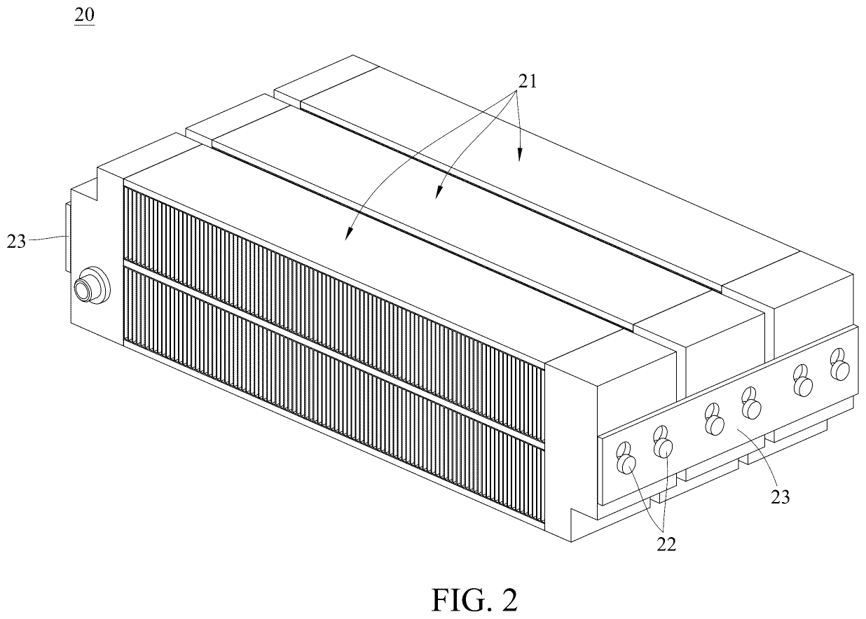

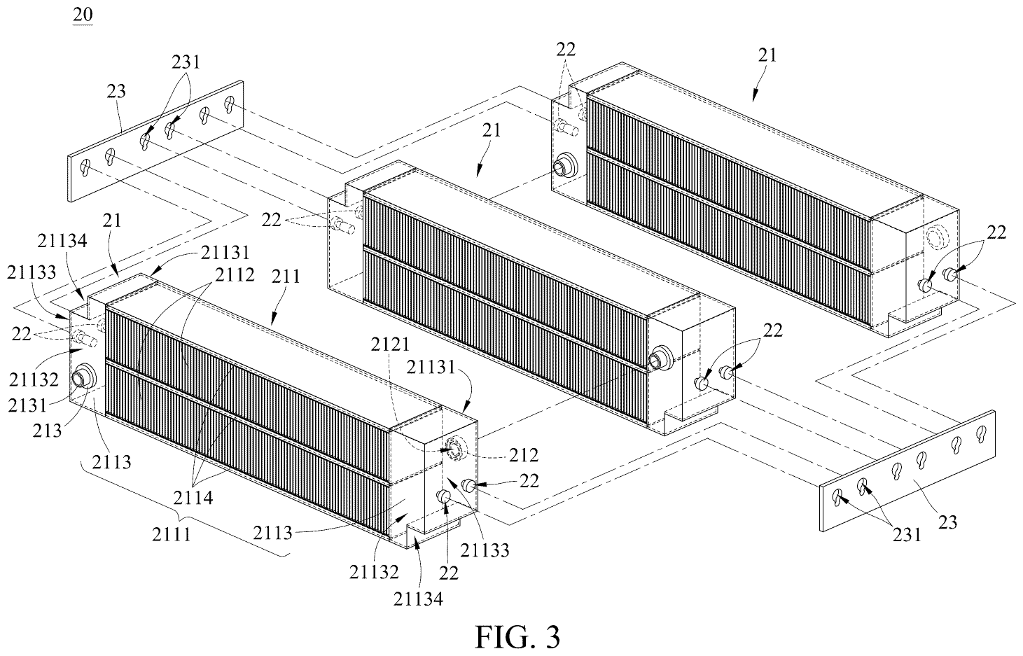

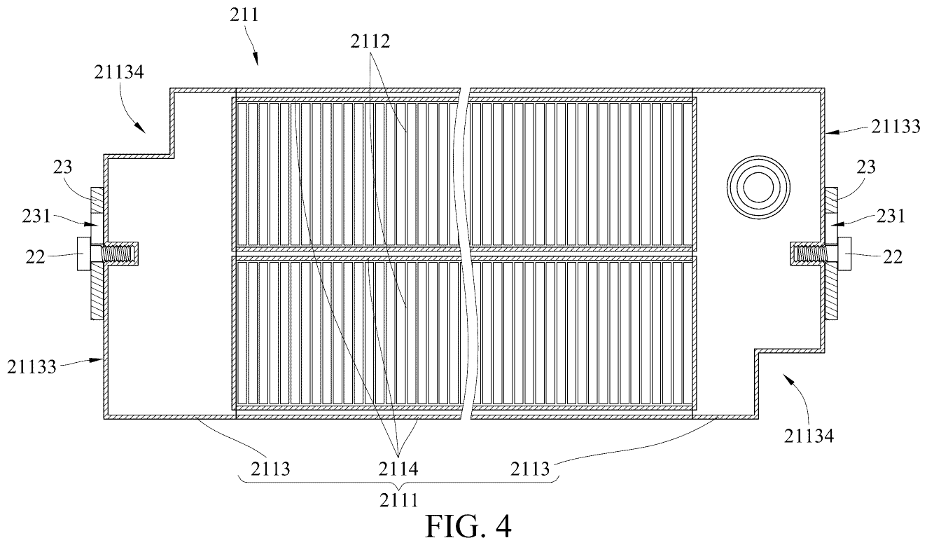

Then, the following paragraphs will specifically introduce the radiator module 20. Referring to FIGS. 2 to 4, FIG. 2 is a perspective view of a radiator module in FIG. 1, FIG. 3 is an exploded view of the radiator module in FIG. 2, and FIG. 4 is a cross-sectional view of a radiator unit in FIG. 2.

The radiator module 20 includes a plurality of radiator units 21. These radiator units 21 are the same in structure, and thus the following descriptions merely introduce one of them. The radiator unit 21 includes a main body 211 and two expansion joints 212 and 213. The main body 211 includes a channel portion 2111 and two fin portions 2112. The two fin portions 2112 are disposed on the channel portion 2111, and the two expansion joints 212 and 213 are respectively disposed at two opposite sides of the channel portion 2111. Specifically, the channel portion 2111 includes two tank parts 2113 and three connection parts 2114. The three connection parts 2114 are located between and connected to the two tank parts 2113. The two tank parts 2113 and the three connection parts 2114 are hollow, and the coolant can flow from one of the tank parts 2113 to the other one of the tank parts 2113 through the three connection parts 2114. The fin portions 2112 are disposed between the three connection parts 2114.

Note that the quantity of the connection parts 2114 and the quantity of the fin portions 2112 are not restricted in the disclosure. In some other embodiments, the quantity of the connection part may be another number, such as two or one, and the quantity of the fin portions may be another number, such as one. Moreover, the quantity of the tank parts 2113 of the channel portion 2111 is not restricted in the disclosure and may be modified to be one.

Each of the two tank parts 2113 has a first surface 21131, a second surface 21132 and a third surface 21133. Taking one of the tank parts 2113 for illustration, the first surface 21131 and the second surface 21132 respectively face two opposite directions, and the third surface 21133 is connected to the first surface 21131 and the second surface 21132. Taking the two tank parts 2113 for illustration, the first surfaces 21131 of the two tank parts 2113 face the same direction, the second surfaces 21132 of the two tank parts 2113 face the same direction, and the third surfaces 21133 of the two tank parts 2113 respectively face two opposite directions. The two expansion joints 212 and 213 are respectively disposed through the first surface 21131 of one of the tank parts 2113 and the second surface 21132 of the other one of the tank parts 2113, and the two expansion joints 212 and 213 respectively communicate with the two tank parts 2113. The expansion joint 212 has a first mount portion 2121, and the expansion joint 213 has a second mount portion 2131. The first mount portion 2121 and the second mount portion 2131 are, for example, a hole and a protrusion mating each other. For example, the first mount portion 2121 is an insertion hole, and the second mount portion 2131 is an insertion pillar.

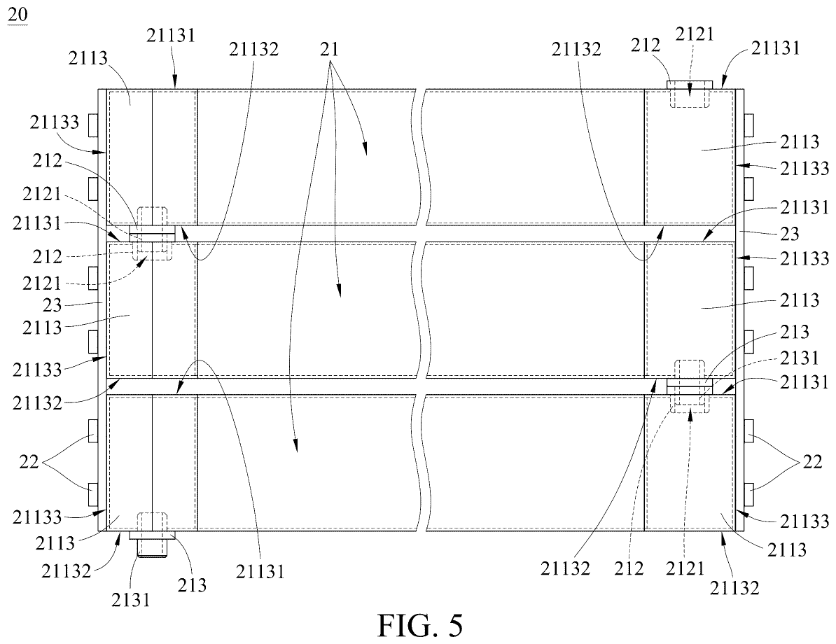

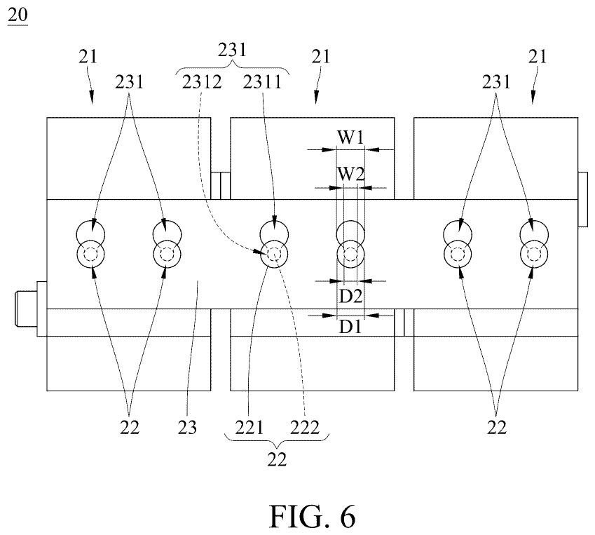

Referring to FIGS. 3 to 6, FIG. 5 is a top view of the radiator module in FIG. 2, and FIG. 6 is a side view of the radiator module in FIG. 2.

In this embodiment, the radiator units 21 are assembled with one another via the expansion joints 212 and 213. Specifically, in any two of the radiator units 21 assembled with each other, the second mount portion 2131 of the expansion joint 213 of one of the radiator units 21 is inserted into the first mount portion 2121 of the expansion joint 212 of the other one of the radiator units 21. After the radiator units 21 are assembled with one another, the radiator units 21 are arranged parallel, some of the tank parts 2113 are located at one side (e.g., a left side) of the radiator module 20, and the other of the tank parts 2113 are located at another side (e.g., a right side) of the radiator module 20. In addition, an interior channel formed in the radiator units 21 assembled with one another is in a S shape.

In this embodiment, each of the two tank parts 2113 of each of the radiator units 21 has an accommodation recess 21134 located at the third surface 21133. The accommodation recesses 21134 of the tank parts 2113 located at two opposite sides of the radiator module 20 are configured to accommodate a pipe (e.g., the pipe P2 shown in FIG. 1) for facilitating the arrangement of the pipe.

Note that the accommodation recesses 21134 of the tank parts 2113 of each of the radiator units 21 are optional structures and may be omitted in some other embodiments.

In this embodiment, the radiator module 20 may further include a plurality of first fasteners 22 and two second fasteners 23. The second fasteners 23 are fixed on the third surfaces 21133 of the two tank parts 2113 of each of the radiator units 21 via the first fasteners 22.

Specifically, the first fasteners 22 are provided on the third surfaces 21133 of the two tank parts 2113 of each of the radiator units 21. One of the second fasteners 23 is engaged with some of the first fasteners 22 disposed on the tank parts 2113 located at one side of the radiator module 20, and the other one of the second fasteners 23 is engaged with the other of the first fasteners 22 disposed on the tank parts 2113 located at another side of the radiator module 20.

The following description will further introduce how the first fasteners 22 are engaged with the second fasteners 23. Each of the second fasteners 23 has a plurality of engagement holes 231, and these engagement holes 231 are respectively engaged with the first fasteners 22. Taking one engagement hole 231 and one first fastener 22 for instance, the engagement hole 231 has a release portion 2311 and an engagement portion 2312 connected to each other, and the first fastener 22 includes a head portion 221 and a neck portion 222 connected to each other. A width D1 of the head portion 221 is greater than a width D2 of the neck portion 222, and the width D1 of the head portion 221 is smaller than a width W1 of the release portion 2311 and is greater than a width W2 of the engagement portion 2312. The neck portions 222 of the first fasteners 22 are respectively located in the engagement portions 2312 of the engagement holes 231 of the two second fasteners 23. One of the second fasteners 23 is located between the head portions 221 of some of the first fasteners 22 and the third surfaces 21133 of the tank parts 2113 located at one side of the radiator module 20, and the other one of the second fasteners 23 are located between the head portions 221 of the other of the first fasteners 22 and the third surfaces 21133 of the tank parts 2113 located at another side of the radiator module 20.

In this embodiment, the channel portion 2111 of the main body 211 of each of the radiator unit 21 is provided with the two expansion joints 212 and 213, and the channel portions 2111 of the main bodies 211 of the radiator units 21 are assembled with one another via the expansion joints 212 and 213 so as to become a module. Therefore, a user can choose the quantity of the radiator units 21 which are desired to be assembled with one another according to heat dissipation requirement. As a result, there is no need to spend a lot of time in designing different heat dissipation module for meeting different heat dissipation requirements, thereby improving manufacturing efficiency and reducing manufacturing cost.

In addition, the channel portions 2111 of the main bodies 211 of the radiator units 21 are assembled with one another via the expansion joints 212 and 213 with holes and protrusions mating each other, which enables the radiator module 20 to be assembled rapidly according to the heat dissipation requirement.

Note that the expansion joints 212 and 213 of each of the radiator units 21 are not restricted to having the first mount portion 2121 and the second mount portion 2131, respectively. In some other embodiments, the two expansion joints of each of the radiator units may be any suitable type of joints.

In addition, the channel portions 2111 of the main bodies 211 of the radiator units 21 are assembled with one another via the expansion joints 212 and 213 so as to become a module, which improves the heat dissipation efficiency of the radiator module 20. For example, after computer simulation, the temperature of the coolant after passing through a one-piece radiator module and other radiator modules with different amount of radiator units is presented in the following table, where these radiator modules have the same size.

| | | Radiator | Radiator | Radiator |
|---|---|---|---|---|
| | | module with | module with | module with |
| | One-piece | two radiator | three radiator | four radiator |
| Scenario | radiator module | units | units | units |
| Temperature | 60 | 60 | 60 | 60 |
| (° C.) of coolant | | | | |
| at inlet of | | | | |
| radiator module | | | | |
| Temperature | 39 | 37.1 | 36 | 35.9 |
| (° C.) of coolant | | | | |
| at outlet of | | | | |
| radiator module | | | | |
| Difference | 21 | 22.9 | 24 | 24.1 |
| between | | | | |
| temperatures | | | | |
| (° C.) of coolant | | | | |
| at inlet and | | | | |
| outlet | | | | |

From the above table, it can be understood that the modularized radiator module increases the length of flowing path of the coolant, thereby improving the heat dissipation efficiency thereof compared to the one-piece radiator module. In addition, as presented by the simulation, the flowing velocity distribution of the coolant flowing through the radiator units assembled with one another is stable and will not varied as the flowing distance of the coolant increases. Moreover, the flow rate of the coolant flowing through the radiator units assembled with one another is also stable.

In this embodiment, the sizes of the radiator units 21 of the radiator module 20 are the same, but the disclosure is not limited thereto. In some other embodiments, the radiator module may be formed from different sizes of the radiator units assembled with one another according to the heat dissipation requirement and a space for the placement of the radiator module, thereby meeting the heat dissipation requirement while effectively using such space.

In this embodiment, the radiator units 21 of the radiator module 20 are fixed to one another via the engagements between the first fasteners 22 and the engagement holes 231 of the second fasteners 23 for preventing the radiator units 21 from being detached from one another.

Note that the structures of the first fasteners 22 and the structures of the engagement holes 231 of the second fastener 23 are not restricted in the disclosure. In some other embodiments, the first fasteners may be pillars with uniform widths, and the engagement holes of the second fasteners may be holes with shapes mating the pillars, and the pillars and the holes are engaged with each other via a tight fit manner.

In addition, the quantity of the second fasteners 23 are not restricted in the disclosure and may be modified to be one in some other embodiments. In such a configuration, some of the first fasteners disposed on the tank parts located at one side of the radiator module may be omitted. Alternatively, the first fasteners may be modified to be disposed on the connection parts located at the same side (e.g., the top side) of the radiator module, and the second fastener is engaged with the first fasteners.

Moreover, the second fasteners 23 are not restricted to being fixed on the radiator units 21 via the first fasteners 22 by an engagement manner. In some other embodiments, the second fasteners may be fixed on the radiator units via the first fasteners which are screws and screwed on the radiator units.

On the other hand, the first fasteners 22 and the second fasteners 23 are optional components and may be modified in some other embodiments.

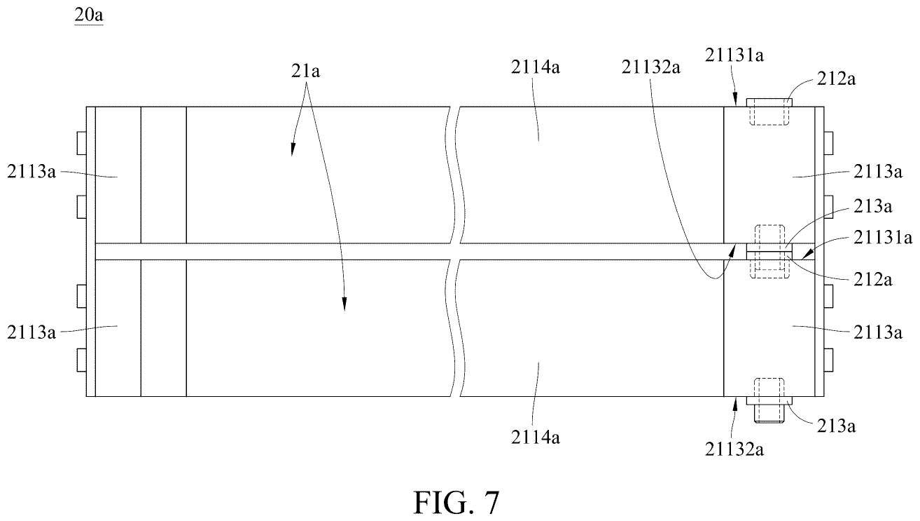

Then, referring to FIG. 7, FIG. 7 is a top view of a radiator module according to a second embodiment of the disclosure.

The radiator module 20a of this embodiment is similar to the radiator module 20 of the previous embodiment, the main difference between them is positions of the two expansion joints of each of the radiator units, and the following paragraphs mainly introduce such difference while the same parts between them will not be repeatedly introduced hereinafter.

In this embodiment, the radiator module 20a, for example, includes two radiator units 21a. Two expansion joints 212a and 213a of each of the radiator units 21a are disposed on a same tank part 2113a, and are located at a first surface 21131a and a second surface 21132a of this tank part 2113a located opposite to each other. As a result, the expansion joints 212a and 213a of the two radiator units 21a are located at a same side of the radiator module 20a, and the expansion joint 212a of one of the radiator units 21a is assembled with the expansion joint 213a of the other one of the radiator units 21a.

In each of the radiator units 21a of this embodiment, the flowing path of the coolant in the radiator unit 21a may be in a U shape via the design of the interior channel thereof. In other words, the coolant entering into one of the tank parts 2113a from the expansion joint 213a will flow through a connection part 2114a and the other one of the tank parts 2113a before the coolant flows out of the tank part 2113a from the expansion joint 212a.

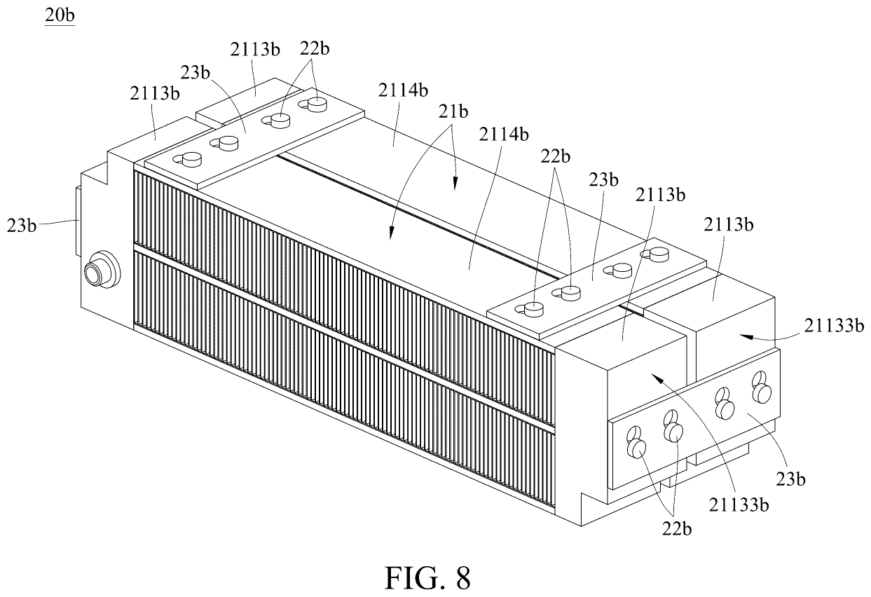

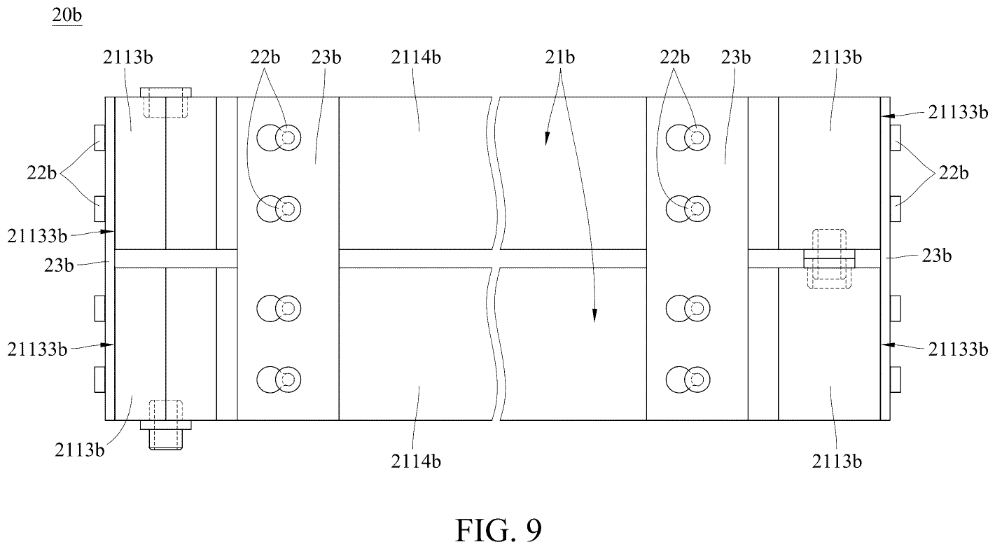

Then, referring to FIGS. 8 and 9, FIG. 8 is a perspective view of a radiator module according to a third embodiment of the disclosure, and FIG. 9 is a top view of the radiator module in FIG. 8.

The radiator module 20b of this embodiment is similar to the radiator module 20 of the previous embodiment, the main differences between them are the quantity of the second fastener and its position, and the following paragraphs mainly introduce such differences while the same parts between them will not be repeatedly introduced hereinafter.

In this embodiment, first fasteners 22b of the radiator module 20b are disposed on not only third surfaces 21133b of two tank parts 2113b of each of radiator units 21b but also a connection part 2114b of each of the radiator units 21b. In addition, the radiator module 20b includes four second fasteners 23b. Two of the second fasteners 23b are fixed on the third surfaces 21133b of the two tank parts 2113b of each of the radiator units 21b via some of the first fasteners 22b. The other two of the second fasteners 23b are fixed on surfaces of the connection parts 2114b of the radiator units 21b facing a same direction via the other of the first fasteners 22b.

According to the radiator units, the radiator modules and the server as discussed in the above embodiments, the channel portion of the main body of each of the radiator unit is provided with the two expansion joints, and the channel portions of the main bodies of the radiator units are assembled with one another via the expansion joints so as to become a module. Therefore, a user can choose the quantity of the radiator unit which are desired to be assembled with one another according to heat dissipation requirement. As a result, there is no need to spend a lot of time in designing different heat dissipation module for meeting different heat dissipation requirements, thereby improving manufacturing efficiency and reducing manufacturing cost.

In addition, the channel portions of the main bodies of the radiator units are assembled with one another via the expansion joints with holes and protrusions mating each other, which enables the radiator module to be assembled rapidly according to the heat dissipation requirement.

Moreover, the channel portions of the main bodies of the radiator units are assembled with one another via the expansion joints so as to become a module, which improves the heat dissipation efficiency of the radiator module.

Furthermore, the radiator module may be formed from different sizes of the radiator units assembled with one another according to the heat dissipation requirement and a space for the placement of the radiator module, thereby meeting the heat dissipation requirement while effectively using such space.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A radiator module, comprising:
a plurality of radiator units, each comprising:
a main body, comprising a channel portion; and
two expansion joints, communicating with the channel portion;
wherein the channel portions of the main bodies of the plurality of radiator units are assembled with one another via the expansion joints.

2. The radiator module according to claim 1, wherein in each of the plurality of radiator units, one of the two expansion joints has a first mount portion, the other one of the two expansion joints has a second mount portion, and the first mount portion and the second mount portion are respectively a hole and a protrusion mating each other.

3. The radiator module according to claim 1, wherein in each of the plurality of radiator units, the two expansion joints are respectively disposed through two ends of the channel portion.

4. The radiator module according to claim 1, wherein in each of the plurality of radiator units, the main body further comprises a fin portion, the channel portion comprises two tank parts and a connection part, the connection part is located between and connected to the two tank parts, the fin portion is disposed on the connection part, and the two expansion joints are respectively disposed through two surfaces of the two tank parts respectively facing two opposite directions.

5. The radiator module according to claim 1, wherein in each of the plurality of radiator units, the main body further comprises a fin portion, the channel portion comprises two tank parts and a connection part, the connection part is located between and connected to the two tank parts, the fin portion is disposed on the connection part, and the two expansion joints are respectively disposed through two surfaces of one of the two tank parts respectively facing two opposite directions.

6. The radiator module according to claim 1, wherein in each of the plurality of radiator units, the channel portion has two accommodation recesses located opposite to each other.

7. The radiator module according to claim 1, further comprising a plurality of first fasteners and at least one second fastener, wherein the at least one second fastener is fixed to the channel portions of the main bodies of the plurality of radiator units via the plurality of first fasteners.

8. The radiator module according to claim 7, wherein the at least one second fastener has a plurality of engagement holes, each of the plurality of engagement holes has a release portion and an engagement portion connected to each other, each of the plurality of first fasteners has a head portion and a neck portion connected to each other, a width of the head portion is greater than a width of the neck portion, the width of the head portion is smaller than a width of the release portion and is greater than a width of the engagement portion; the neck portions of the plurality of first fasteners are respectively located at the engagement portions of the plurality of engagement holes of the at least one second fastener, and the at least one second fastener is located between the head portions of the plurality of first fasteners and the channel portions of the main bodies of the plurality of radiator units.

9. The radiator module according to claim 7, wherein in each of the plurality of radiator units, the main body further comprises a fin portion, the channel portion comprises two tank parts and a connection part, the connection part is located between and connected to the two tank parts, the fin portion is disposed on the connection part; the at least one second fastener comprises two second fasteners, and the two second fasteners are fixed on two surfaces of the two tank parts of each of the plurality of radiator units respectively facing two opposite directions via the plurality of first fasteners.

10. The radiator module according to claim 7, wherein in each of the plurality of radiator units, the main body further comprises a fin portion, the channel portion comprises two tank parts and a connection part, the connection part is located between and connected to the two tank parts, the fin portion is disposed on the connection part; the at least one second fastener is fixed on surfaces of the connection parts of the plurality of radiator units facing a same direction via the plurality of first fasteners.

11. A server, comprising:
a casing; and
a radiator module, located in the casing and comprising:
a plurality of radiator units, each comprising:
a main body, comprising a channel portion; and
two expansion joints, communicating the channel portion;
wherein the channel portions of the main bodies of the plurality of radiator units are assembled with one another via the expansion joints.

12. The server according to claim 11, wherein in each of the plurality of radiator units, the two expansion joints are respectively disposed through two ends of the channel portion.

13. The server according to claim 11, wherein in each of the plurality of radiator units, the main body further comprises a fin portion, the channel portion comprises two tank parts and a connection part, the connection part is located between and connected to the two tank parts, the fin portion is disposed on the connection part, and the two expansion joints are respectively disposed through two surfaces of the two tank parts respectively facing two opposite directions.

14. The server according to claim 11, wherein in each of the plurality of radiator units, the main body further comprises a fin portion, the channel portion comprises two tank parts and a connection part, the connection part is located between and connected to the two tank parts, the fin portion is disposed on the connection part, and the two expansion joints are respectively disposed through two surfaces of one of the two tank parts respectively facing two opposite directions.

15. A radiator unit, configured to be assembled with another radiator unit, comprising:
a main body, comprising a channel portion; and
two expansion joints, communicating with the channel portion, wherein one of the two expansion joints is configured to be assembled with the another radiator unit.

16. The radiator unit according to claim 15, wherein the two expansion joints are respectively disposed through two ends of the channel portion.

17. The radiator unit according to claim 15, wherein the main body further comprises a fin portion, the channel portion comprises two tank parts and a connection part, the connection part is located between and connected to the two tank parts, the fin portion is disposed on the connection part, and the two expansion joints are respectively disposed through two surfaces of the two tank parts respectively facing two opposite directions.

18. The radiator unit according to claim 15, wherein the main body further comprises a fin portion, the channel portion comprises two tank parts and a connection part, the connection part is located between and connected to the two tank parts, the fin portion is disposed on the connection part, and the two expansion joints are respectively disposed through two surfaces of one of the two tank parts respectively facing two opposite directions.

19. The radiator unit according to claim 15, wherein one of the two expansion joints has a first mount portion, the other one of the two expansion joints has a second mount portion, and the first mount portion and the second mount portion are respectively a hole and a protrusion mating each other.

20. The radiator unit according to claim 15, wherein the channel portion has two accommodation recesses located opposite to each other.
